(19) United States
(12) Patent Application Publication
(10) Pub. No.: US 2008/0048817 A1
(43) Pub. Date: Feb. 28, 2008

(54) CIRCUIT MODULE

(75) Inventor: Imad Mahawili, Grand Haven, MI (US)

Correspondence Address: VAN DYKE, GARDNER, LINN & BURKHART, LLP, SUITE 207, 2851 CHARLEVOIX DRIVE, S.E., GRAND RAPIDS, MI, 49546, US

(73) Assignee: ENERGY RECOVERY TECHNOLOGY, LLC, Grand Haven, MI (US)

(21) Appl. No.: 11/828,686

(22) Filed: Jul. 26, 2007

Related U.S. Application Data
(60) Provisional application No. 60/833,373, filed on Jul. 26, 2006.

(51) Int. Cl. H01F 27/30; H01R 43/00; H05K 3/10

(52) U.S. Cl. 336/206; 29/825; 29/846

(57) ABSTRACT

A circuit module includes a flexible sheet of non-conductive material that is sufficiently flexible to permit the sheet to be rolled and which supports a circuit. The circuit has at least one loop and first and second contacts for coupling the loop to an external device.

### CROSS-REFERENCE TO RELATED APPLICATIONS

This application claims priority from U.S. provisional application Ser. No. 60/833,373, filed Jul. 26, 2006, entitled CIRCUIT MODULE, by Applicant Imad Mahawili, Ph.D, and is incorporated herein in its entirety.

### TECHNICAL FIELD AND BACKGROUND OF THE INVENTION

The present invention relates to a circuit and, more particularly, to a circuit module that may be used, for example, in the energy recovery system disclosed in copending application Ser. No. 11/454,948, filed Jun. 16, 2006, entitled ENERGY RECOVERY SYSTEM, by Imad Mahawili, Ph.D, Attorney Docket No. ENE02 P-105, which is incorporated by reference herein in its entirety.

### SUMMARY OF THE INVENTION

The present invention provides a circuit module that includes a flexible sheet of non-conductive material which is sufficiently flexible to permit the sheet to be rolled and which supports a circuit. The circuit has at least one loop and first and second contacts for coupling the loop to an external device.

In one aspect, the circuit includes a plurality of loops. In a further aspect, each of the loops includes a diode.

In another aspect, the loop forms an alternating current circuit when a magnetic field is passed by the loop. Optionally, the circuit may include a rectifier, which converts the alternating current circuit to a direct current circuit. For example, the rectifier may comprise a diode or a diode bridge.

In any of the above circuit modules, the flexible sheet may comprise a polymer sheet, such as a polyester sheet, including a polyethylene sheet, such as a biaxially-oriented polyethylene terephthalate (boPET) sheet. Another suitable polymer sheet includes a polyvinyl chloride (PVC) sheet. Alternately, the flexible sheet may comprise a paper sheet, including tar paper.

Further, in any of the above circuit modules, the loop may be formed from a conductive path, such as a metal oxide path or a metal path, that is deposited on the flexible sheet.

In another aspect, the flexible sheet may comprise a first side and a second side, with the loop forming a first conductive path on the first side and a second conductive path on the second side.

According to another form of the invention, a circuit is formed by a flexible sheet of non-conductive material, which is sufficiently flexible to permit the sheet to be rolled, and a circuit loop that is formed on the flexible sheet. Contacts for the circuit loop are provided for coupling the circuit loop to an external device.

In one aspect, the circuit loop is formed by depositing a conductive substance on the flexible sheet. Suitable conductive substances include a metal oxide or metal. The conductive substance may be deposited and then etched to form the circuit loop. Alternately, portions of the flexible sheet may be masked when depositing the conductive substance on the flexible sheet so that the unmasked portions are deposited with the conductive substance.

The conductive substance may be deposited using a vacuum deposition or evaporation, or by sputtering the conductive substance onto the flexible sheet.

In a further aspect, when forming the circuit loop, the loop may be configured to form an AC circuit on the flexible sheet.

In another aspect, the circuit loop may be provided with a rectifier to convert the AC circuit to a DC circuit. For example, the circuit may be provided with a diode or diode bridge.

In yet another form of the invention, a circuit module includes a substrate formed from a non-conductive material and a circuit. The substrate includes a plurality of recesses formed therein for receiving at least portions of the circuit.

For example, the substrate may be formed from a ground surface, such as tar, concrete, or from a material that is suitable for use as a ground surface, at least over a limited region, such as a polymer, including a reinforced polymer. The recesses may be preformed in the substrate or may be formed such as by cutting. Alternately, the recesses may be formed by heating and melting the substrate in discrete regions while at the same time the circuit is embedded into the melted portions of the substrate surface.

In one aspect, the portions of the circuit that are located in the recesses may be sealed in the recesses either by the substrate material itself if a melt/embedment process is used or by a sealant, such as a polymer seal. Alternately or in addition, the entire surface of the substrate in the vicinity of the circuit may be covered with a non-magnetic material, such as a layer of a polymeric material or a layer of tar, in the case of a tar or concrete substrate, for example.

Accordingly, the present invention provides a circuit that is flexible, which facilitates installation of the circuit especially when used in conjunction with the energy recovery system described in the above referenced pending application.

These and other objects, advantages, purposes, and features of the invention will become more apparent from the study of the following description taken in conjunction with the drawings.

### DETAILED DESCRIPTION OF THE DRAWINGS

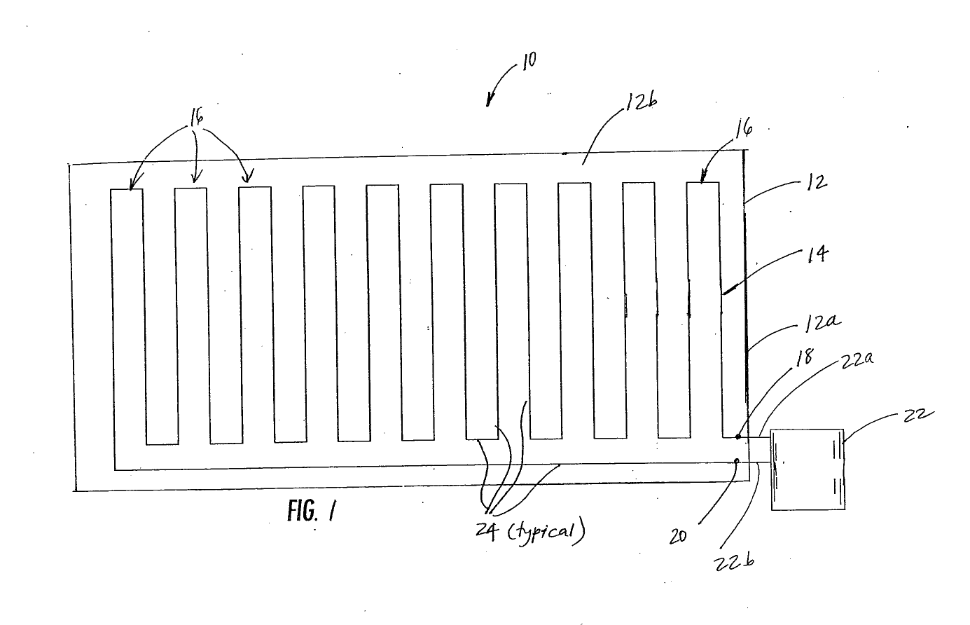

FIG. 1 is a schematic view of a circuit module of the present invention;

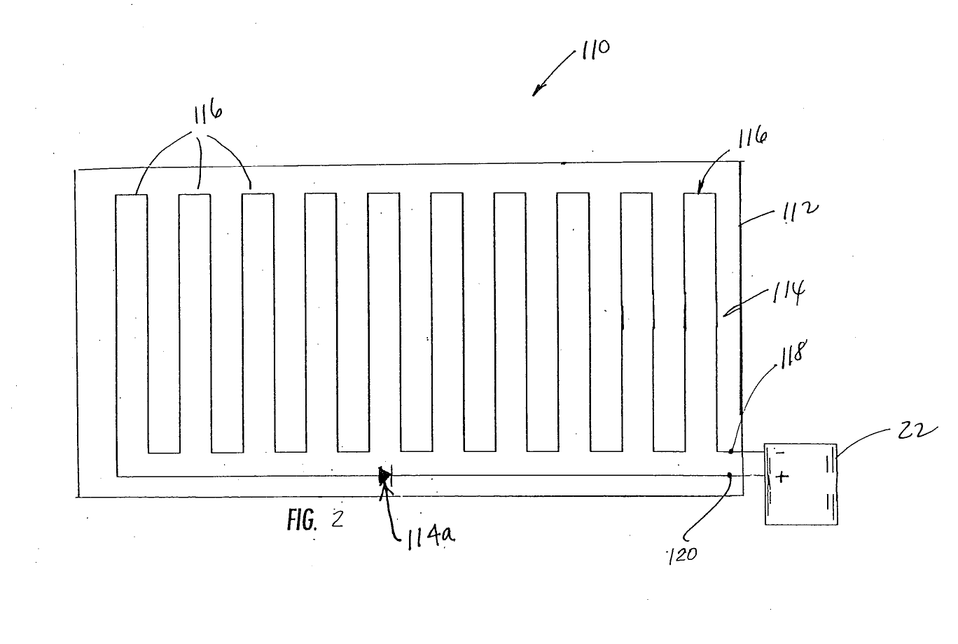

FIG. 2 is a schematic view of a second embodiment of the circuit module of the present invention;

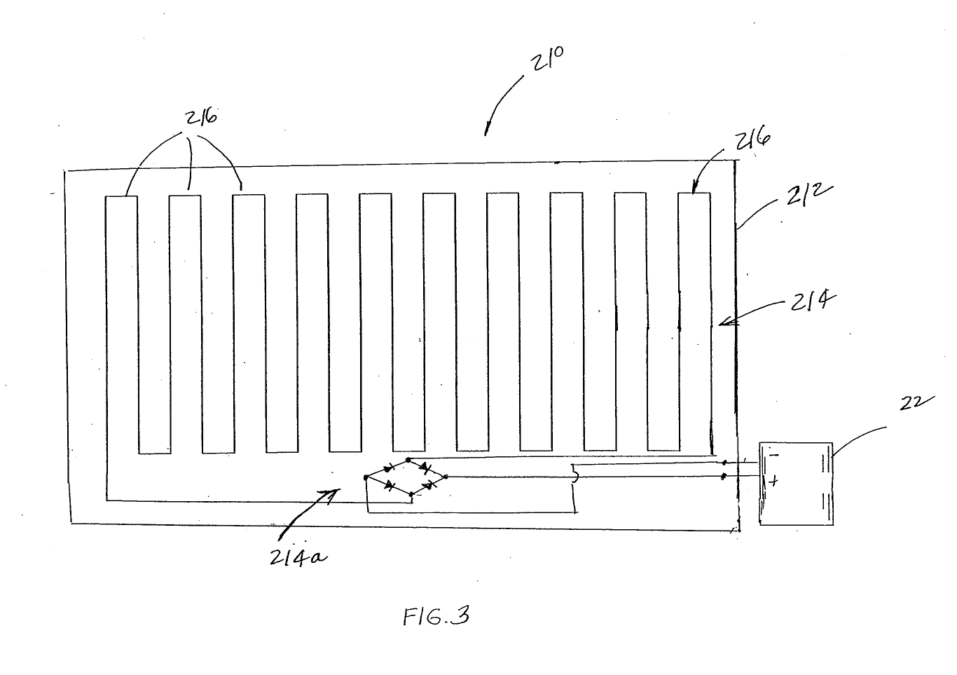

FIG. 3 is a schematic view of a third embodiment of the circuit module of the present invention;

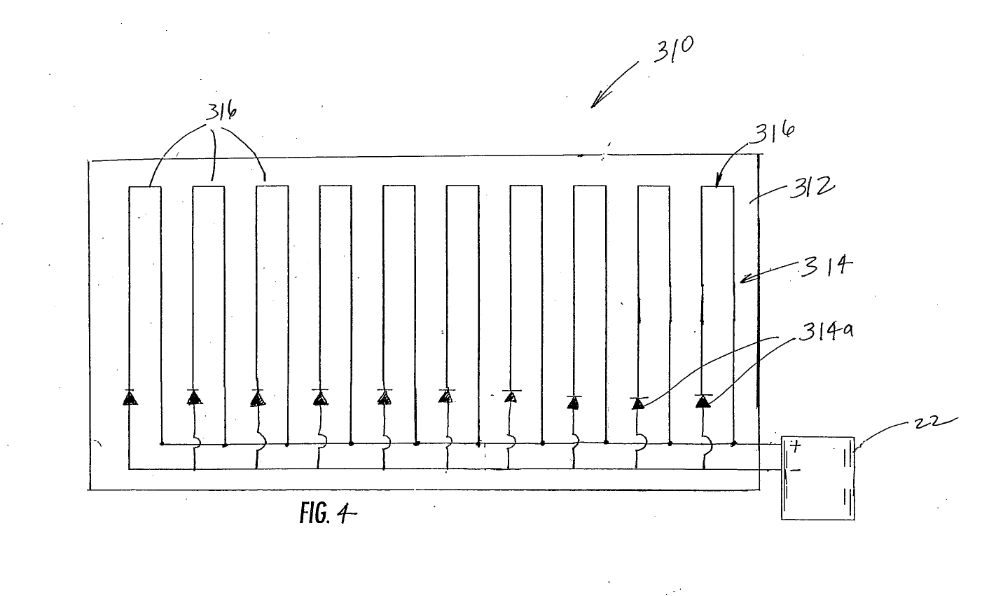

FIG. 4 is a schematic view of a fourth embodiment of the circuit module of the present invention; and

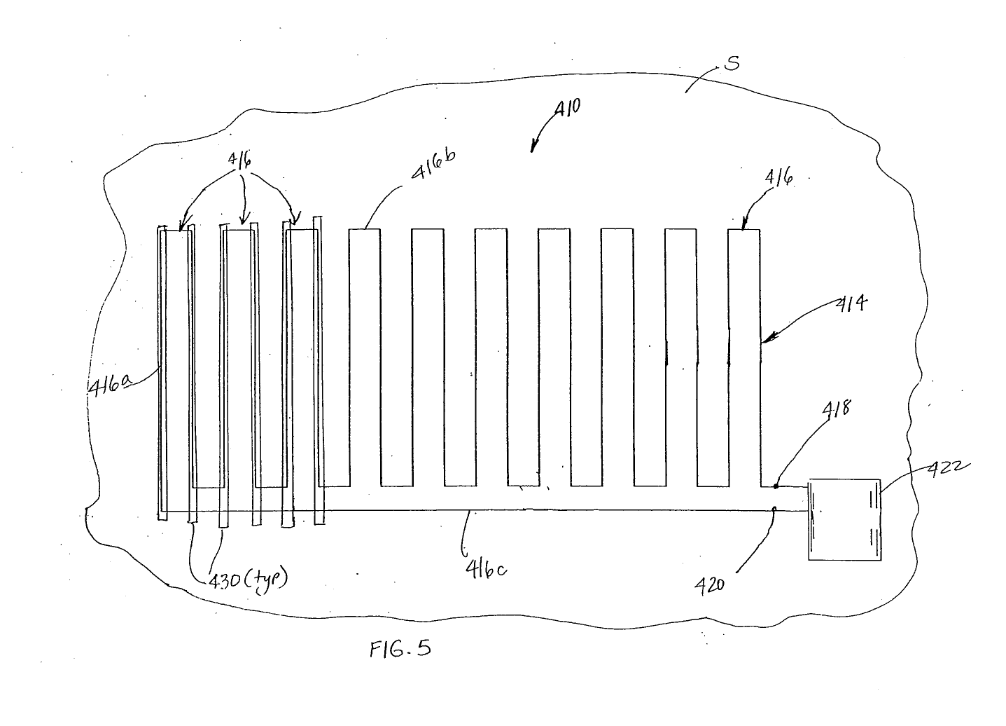

FIG. 5 is a schematic view of a fifth embodiment of the circuit module of the present invention.

### DETAILED DESCRIPTION OF THE PREFERRED EMBODIMENTS

Referring to FIG. 1, the numeral 10 generally designates a circuit module of the present invention. Circuit module 10 is particularly suitable for use in the energy recovery system described in copending application Ser. No. 11/454,948, filed Jun. 16, 2006, entitled ENERGY RECOVERY SYSTEM, by Applicant Imad Mahawili, Ph.D (Attorney Docket No. ENE02 P-105), which is incorporated by reference herein in its entirety. The energy recovery system as described in the referenced application provides a magnetic field generator mounted to a moving object, such as a vehicle, and a stationary circuit mounted, for example, in the ground or road surface which generates electricity when the magnetic field generator passes by the circuit. Although described in reference to a moving magnetic field generator and a stationary circuit, it should be understood that the circuit may be mounted to the vehicle, and the magnetic field generator mounted to the stationary surface, with one or more of the circuit modules of the present invention equally suitable for use.

As will be more fully described below, circuit module 10 is configured to provide a flexible circuit that can be rolled, for example about a reel or drum or the like, so that the circuit can be stored in a compact arrangement and, further, easily deployed for use for example, in the energy recovery system application referenced above. Furthermore, as will be appreciated from the following description, circuit module 10 may be configured such that it can be adjusted in size to suit the particular application. Alternately, as described more fully below in reference to FIG. 5, the circuit may be embedded in a substrate, such as the ground or road surface.

Referring to FIG. 1, in the illustrated embodiment, circuit module 10 includes a flexible substrate 12 in the form of a flexible sheet or film and a circuit 14, which is supported by substrate 12. Substrate 12 may be formed from a flexible sheet of non-conductive material, such as a polymer sheet, paper, or tar paper. Suitable polymer sheets include polyester sheets, including a polyethylene sheet, such as a biaxially-oriented polyethylene terephthalate (boPET) sheet, which is commercially available under the tradename MYLAR. Other suitable polymer sheets include a polyvinyl chloride (PVC) sheet.

Circuit 14 may include one or more loops 16 that are arranged on the sheet. In the illustrated embodiment, circuit 14 includes a plurality of loops 16 that are arranged in series and arranged on the sheet in a plane. It should be understood that the number of loops can be varied—increased or decreased—depending on the application, including as noted decreased to a single loop. Circuit 14 includes a pair of contacts 18 and 20 for coupling circuit 14 to an external device 22. Contacts 18 and 20 may be provided on sheet 12 and located within outer perimeter 12a of sheet 12 or may project from perimeter 12a of sheet 12 for coupling to the leads 22a and 22b of external device 22.

Loops 16 are formed from a plurality of conductive paths 24 that are provided on surface 12b of sheet 12. For example, conductive paths 24 may be formed from metal or metal oxide paths, which are formed by deposits of a conductive substance on sheet 12 using conventional deposition methods. In one form, the conductive paths are arranged such that the loops, which as noted above, are arranged in series and, further, are arranged in an array on one side of the sheet, along with the common conductive path that couples to the first loop and forms or couples to contact 18. The other common conductive path that couples to the last loop extends along the other side of the sheet to then form or couple to contact 20 for coupling to the external device. Although only one array is illustrated it should be understood that a sheet may include a plurality of arrays that are interconnected to the common conductive paths of the adjacent array, but with each array then optionally including a diode to control the flow of current from each array through the common conductive paths and then to the common external device. When the sheet supports multiple arrays, it is also contemplated that the length of the sheet, and therefore the number of arrays, maybe adjusted by simply cutting off a section of the sheet between two adjacent arrays. In this manner the circuit can be adjusted to suit a particular application without any significant rework.

The conductive substance may be deposited on sheet 12, for example, using vacuum deposition, evaporation, or sputtering or the like. Further, the circuit may be formed by etching the conductive substance that is deposited on sheet 12. Alternately, the circuit may be formed by masking portions of the flexible sheet when the conductive substance is deposited on the sheet. Suitable conductive substances include metals, such as copper, aluminum, silver, or the like, or metal oxides such as indium tin oxide or the like.

As described in the copending application entitled ENERGY RECOVERY SYSTEM, referenced above, when a magnetic field is passed across a plurality of conductive loops, the change in the magnetic field due to the movement of the magnet across the conductive paths induces current flow through the conductive paths and, in the illustrated embodiment, produces an alternating current through circuit 14. As described in the copending application, the alternating current may be delivered to an external device, such as external device 22, which may comprise an energy storage device, such as a battery or a capacitor, which stores the energy generated by the current flowing through the circuit or may comprise a transformer, which steps up the voltage to directly feed the energy to a power grid. In the case of an energy storage device a direct current is needed; therefore, as described below, the circuit module of the present embodiment may also incorporate a rectifier to convert the alternating current (AC) into a direct current (DC).

Referring to FIG. 2, the numeral 110 generally designates another embodiment of the circuit module of the present invention. Circuit module 110 is of similar construction to module 10 and includes a flexible sheet 112 of non-conductive material and one or more loops, which form an AC circuit when the magnet is passed across the loops as described above. For further details of sheet 112 and how circuit 114 is formed on sheet 112, reference is made to the first embodiment.

In the illustrated embodiment, circuit 114 also includes a rectifier 114a in the form of a diode, which only allows one-way flow of current through the diode to device 22. In the illustrated embodiment, rectifier 114a is a half-way rectifier because it only allows one-half of the current wave form to pass through to device 22.

Referring to FIG. 3, the numeral 210 designates yet another embodiment of the circuit module of the present invention. Circuit module 210 includes a flexible sheet of non-conductive material 212 and a circuit 214, which includes one or more loops 216, which may also be arranged in series similar to the previous embodiments.

In the illustrated embodiment, rectifier 214a comprises a diode bridge, which forms a full wave rectifier circuit so that the full capacity of the circuit 214 is delivered to device 22. Other full wave rectifier circuits that may be used include center tap designs which incorporate a transformer. However, the necessity of the center tapped secondary winding may significantly increase the cost of the circuit and, further, may be limited to low power applications. Although illustrated in reference to a single diode bridge, multiple diode bridges may be used to reduce the ripple effect on the voltage output that is associated with a full wave rectifier circuit.

Alternately, referring to FIG. 4, circuit module 310, which similarly includes a flexible sheet of non-conductive material 312 and a circuit 314 formed from one or more loops 316, may be provided with a rectifier 314a for each loop. As will be understood, therefore, the circuit modules of FIGS. 2-4 are rectified to provide a DC output to device 22.

Referring to FIG. 5, the number 410 designates yet another embodiment of the circuit module of the present invention. Circuit module 410 includes a substrate S and a circuit 414, which is at least partially embedded in substrate S. Substrate S may be formed from a portion of a ground or road surface, such as a portion of an asphalt road surface or a portion of a concrete road surface. Alternately, substrate S may be formed from a slab of material, such as a polymer material or an asphalt or concrete slab, that is inserted into a road surface.

Similar to the previous embodiments, circuit 414 includes one or more loops 416 that are optionally generally arranged in a plane, though as will be more fully described below, portions of the loops may be offset from the plane as a result of the topology of substrate S. For further details of loops 416, contacts 418, 420 and external device 422 reference is made to the previous embodiments. Further, it should be noted that circuit 414 may include one or more rectifiers as described in reference to circuits 114, 214, and 314.

As best seen in FIG. 5, substrate S includes one or more recesses 430. At least a portion of circuit 414 is located and embedded in recess 430. For example, in the illustrated embodiment substrate S includes a plurality of recesses 430 that are formed therein, for example by cutting or molding or by melting the substrate such that the circuit can be embedded in the substrate, for example while the melted portion of the substrate is still pliable. Recesses 430 may comprise a plurality of generally parallel elongate recesses that form channels for receiving the transverse sections or portions 416a of each loop. The elongate channels may be interconnected by cross channels (not shown) to receive the interconnecting sections or portions 416b of the loops so that almost the entire circuit 416 may be embedded in substrate S. Alternately, the interconnection portions 416b may extend across the top surface of the substrate and as a result are offset from the plane in which the transverse portions of the loops are arranged. An additional recess or channel that intersects with the last transverse section or portion 416a of the loops may be provided to embed the return loop 416c of circuit 414 that couples to the external device 422.

Further, where the recesses are formed by molding or cutting, the portions of the circuit that are embedded in the substrate may be sealed in the recess or recesses by a sealant, such as a polymeric sealant. Where the circuit is embedded using melt/embedment, the circuit may be sealed by the material forming the substrate as the material cools.

Alternately or in addition, the substrate may be covered with a layer, such as a layer of polymeric material or by a layer of tar or the like. Furthermore, the substrate may include a single recess with the circuit arranged in the recess and then covered and, preferably, sealed in the recess by a non-conductive material such as a polymeric material, tar, or concrete that may be poured in and thereafter set to form a surface over the circuit, preferably that is suitable for use in a road or ground surface.

While several forms of the invention have been shown and described, other forms will now be apparent to those skilled in the art. For example, the conductive paths may be formed on both sides of the sheet to increase the number of loops per linear length of the sheet. Further, as noted above, the circuit may incorporate a single loop. Therefore, it will be understood that the embodiments shown in the drawings and described above are merely for illustrative purposes, and are not intended to limit the scope of the invention, which is defined by the claims, which follow as interpreted under the principles of patent law including the doctrine of equivalents.

The embodiments of the invention in which an exclusive property right or: privilege is claimed are defined as follows:

1. A circuit module comprising:
a flexible sheet of non-conductive material, said sheet being sufficiently flexible to permit said sheet to be rolled; and
said flexible sheet supporting a circuit, said circuit having at least one loop and first and second contacts for coupling said loop to an external device.

2. The circuit module according to claim 1, wherein said circuit includes a plurality of loops.

3. The circuit module according to claim 2, wherein each of said loops includes a diode.

4. The circuit module according to claim 1, wherein said loop forms an alternating current circuit when a magnetic field is passed by said loop.

5. The circuit module according to claim 4, wherein said circuit further includes a rectifier, said rectifier converting said alternating current circuit to a direct current circuit.

6. The circuit module according to claim 5, wherein said rectifier includes at least one diode.

7. The circuit module according to claim 5, wherein said rectifier includes a diode bridge.

8. The circuit module according to claim 1, wherein said flexible sheet comprises a polymer sheet or a paper sheet.

9. The circuit module according to claim 8, wherein said polymer sheet comprises a polyester sheet.

10. The circuit module according to claim 9, wherein said polyester sheet comprises a polyethylene sheet, such as a biaxially-oriented polyethylene terephthalate (boPET) sheet.

11. The circuit module according to claim 8, wherein said polymer sheet comprises a polyvinyl chloride (PVC) sheet.

12. The circuit module according to claim 1, wherein said loop comprises a metal oxide path or a metal path.

13. The circuit module according to claim 1, wherein said flexible sheet comprises a first side and a second side, further comprising a first conductive path on said first side and a second conductive path on said second side, at least one of said conductive paths forming said loop.

14. The circuit module according to claim 13, wherein the other of said conductive paths forms a second loop for coupling to the external device.

15. A circuit module comprising:
a substrate formed form a non-conductive material; and
a circuit, said substrate having at least one recess for receiving at least a portion of the circuit therein wherein said at least a portion of the circuit is embedded in the substrate, and said substrate forming a road surface.

16. The circuit module according to claim 15, wherein said circuit includes a plurality of loops.

17. The circuit module according to claim 16, wherein each of said loops includes a diode.

18. The circuit module according to claim 15, wherein said loop forms an alternating current circuit when a magnetic field is passed by said loop.

19. The circuit module according to claim 18, wherein said circuit further includes a rectifier, said rectifier converting said alternating current circuit to a direct current circuit.

20. The circuit module according to claim 19, wherein said rectifier includes at least one diode.

21. The circuit module according to claim 19, wherein said rectifier includes a diode bridge.

22. A method of forming a circuit comprising:
providing a flexible sheet of non-conductive material, the sheet being sufficiently flexible to permit the sheet to be rolled;
forming a circuit loop on the flexible sheet; and
providing contacts for the circuit loop for coupling the circuit loop to an external device.

23. The method according to claim 22, wherein said forming a circuit loop comprises depositing a conductive substance on the flexible sheet.

24. The method according to claim 23, wherein said depositing a conductive substance includes depositing a metal oxide or a metal on the flexible sheet.

25. The method according to claim 24, wherein said forming further includes masking portions of the flexible sheet when depositing the conductive substance on the flexible sheet.

26. The method according to claim 24, wherein said depositing comprises depositing a conductive substance by vacuum deposition, by evaporating, or by sputtering a conductive substance on the flexible sheet.

27. A method of forming a circuit comprising:
providing a portion of a road surface;
forming at least one recess in the road surface; and
embedding at least a portion of a circuit loop in said recess.

28. The method according to claim 27, wherein said forming at least one recess includes cutting at least one recess.

29. The method according to claim 27, wherein said forming at least one recess and said embedding includes melting the road surface while embedding the circuit in the road surface.

30. The method according to claim 27, wherein said embedding includes embedding at least a portion of a plurality of circuit loops.
